(19) United States
(12) Patent Application Publication
(10) Pub. No.: US 2016/0133772 A1
(43) Pub. Date: May 12, 2016

(54) CONCENTRATING OPTICAL WAVEGUIDE AND CONTAINMENT CHAMBER SYSTEM

(71) Applicant: Robert M. Freda, West Roxbury, MA (US)

(72) Inventor: Robert M. Freda, West Roxbury, MA (US)

(21) Appl. No.: 14/877,977

(22) Filed: Oct. 8, 2015

Related U.S. Application Data
(63) Continuation of application No. 13/029,576, filed on Feb. 17, 2011, now abandoned.
(60) Provisional application No. 61/305,198, filed on Feb. 17, 2010.

(51) Int. Cl. H01L 31/054

(52) U.S. Cl. CPC H01L 31/0547

(57) ABSTRACT

In embodiments of the present invention improved capabilities are described for a concentrating optical waveguide and containment facility comprising wide acceptance angle, high ratio, solar concentrators where the facility operates independent of the need for solar tracking. The invention utilizes unique non-focusing waveguide optics and containment chambers to concentrate and contain incident light such that the effective concentration is the ratio of incident surface area to the power producing element within or at the exit of the containment chamber.

### CROSS-REFERENCE TO RELATED APPLICATIONS

This application is a continuation of U.S. patent application Ser. No. 13/029,576 filed Feb. 17, 2011 (RFRD-0001-P01).

U.S. patent application Ser. No. 13/029,576 claims the benefit of U.S. Provisional Application No. 61/305,198, filed Feb. 17, 2010 (RFRD-0001-P60).

Each of the above patent applications is hereby incorporated by reference in its entirety.

### BACKGROUND

Historically Solar Photovoltaic (PV) power has been expensive when compared to other methods of producing electricity such as fossil or other renewable sources. Types of solar power production, all of which have limitations, include module-based (crystalline, film, and hybrids, among others), concentrating, and thermal. All three categories have been heavily researched for the last 40 years. Thermal is mainly dependent on the engine or generator type used to convert the heat gathered by the system. Module relies primarily on increased chip efficiency and lower chip manufacturing cost. Concentrating historically has traded off the amount of chip or film used for the expense of tracking systems, as the angle of acceptance in a non-tracking system is low. More recently, concentrating film-based systems applied to flat surfaces based on internal reflection have been proposed as a solution, but still accept relatively little light when compared to tracking concentrating systems.

Additionally PV systems have been designed under the premise of extended lifecycles similar to utility (or other industrial or construction systems) design for other power production methods, roughly 20 to 25 years. There is an inherent mismatch in this design paradigm between the largest potential market, the distributed market (smaller end users, local hydrogen production, etc.), the cost of the non-chip systems necessary to sustain this product lifetime (and the attendant lifecycle maintenance and efficiency degradation cost), and the lifetime of the underlying highest efficiency power producing mechanism, the crystalline chip, roughly 75-100+ years.

### SUMMARY

Methods and systems are described herein for PV systems wherein: 1) Wide acceptance angle concentration and thereby chip or film or other conversion mechanism expense reduction may be achieved without the expense or with a minimal expense of or on a tracking mechanism, 2) The components of the system may be designed as modular elements to decouple their lifecycle mismatch allowing amortization and reuse of the more expensive components over multiple system lifecycles, and 3) The cost and/or environmental “wear” parameters of the non-chip system and its installation may be designed around reduced lifecycle parameters more in keeping with the purchasing parameters of largest likely end use of the technology.

The current invention may achieve wide acceptance angle without tracking, and concomitant chip and system expense reduction, by means of a novel concentrator, reflector, refractor, and the like or a combination thereof concentrating facility and reflective, refractive, and the like or a combination thereof containment facility wherein said facilities may be modular in nature and comprised of metal, polymer, composite elements, and the like or any combination thereof and a power producing facility such as PV chip, film, a thermal engine, and the like or any combination thereof either interior or exterior or a combination thereof to the containment facility. Concentration in excess of 100:1 with regard to input to chip area may be achieved with such a system. Such facilities may be designed as independent, combinative, and the like facilities designed to be separated, recondition, recombined and the like at low cost to maximize lifecycle return of the given facilities.

An example may be a polymer, metallic, and the like focusing element molded in a sheet to appear like roofing shingle that may be designed to be installed, placed, molded and the like over a power producing PV chip “sheet” wherein the polymer sheet may be designed for a lifecycle of three years at low cost and wherein the polymer sheet may be designed to be inexpensively laid over the PV chip “sheet” such that its removal and replacement, in situ, on-site, off-site, and the like reconditioning after the period of three years may be performed for minimal cost. In such a case the PV chip “sheet” may remain installed or be refurbished or recycled for multiple polymer sheet lifecycles and the polymer sheet may serve as a focusing and “wear” protective layer to both the PV chip “sheet” and the underlying substrate on which the system is installed such as a roof. Such a system may substantially reduce the cost of the initial system based on reduced chip cost, reduced non-chip cost, reduced installation cost, and incremental lifecycle costs similar to normal maintenance costs associated with non-modular longer lifecycle systems and thereby may reduced the cost and commitment of such a solar facility to acceptable levels to be competitive in the marketplace.

These and other systems, methods, objects, features, and advantages of the present invention will be apparent to those skilled in the art from the following detailed description of the preferred embodiment and the drawings. All documents mentioned herein are hereby incorporated in their entirety by reference.

### BRIEF DESCRIPTION OF THE FIGURES

The invention and the following detailed description of certain embodiments thereof may be understood by reference to the following figures:

FIG. 1 depicts a layered configuration with regard to lifecycle.

FIG. 2 depicts a layered configuration of a power producing facility.

FIG. 3 depicts an example configuration for the power producing facility.

FIG. 4 depicts an embodiment of a concentrator.

FIG. 5 depicts an embodiment of a concentrator, with curved channels.

FIG. 6 depicts an embodiment of a concentrator, with layered fiber optics.

FIG. 7 depicts an embodiment of a concentrator fiber optic plug.

FIGS. 8 and 9 depict fiber optic configurations for focusing light onto a central facility.

FIGS. 10-13 depict various cell configuration embodiments.

FIG. 14 depicts a dual input concentrator embodiment.

FIGS. 15 and 16 depict concentration configuration embodiments.

FIG. 17 depicts an embodiment layered concentrator, power, and containment structure.

FIGS. 18 and 19 depict modular configurations of a concentrating-containment power producing facility.

FIG. 20 depicts an effect of partitioning on the acceptance angle.

FIGS. 21-23 depicts array taper configurations.

FIG. 24 depicts a variable surface, stacked surface configuration.

FIG. 25 depicts waveguide configurations.

FIGS. 26-28 depict a containment facilities comprised of a plurality of surfaces.

While the invention has been described in connection with certain preferred embodiments, other embodiments would be understood by one of ordinary skill in the art and are encompassed herein.

All documents referenced herein are hereby incorporated by reference.

### DETAILED DESCRIPTION

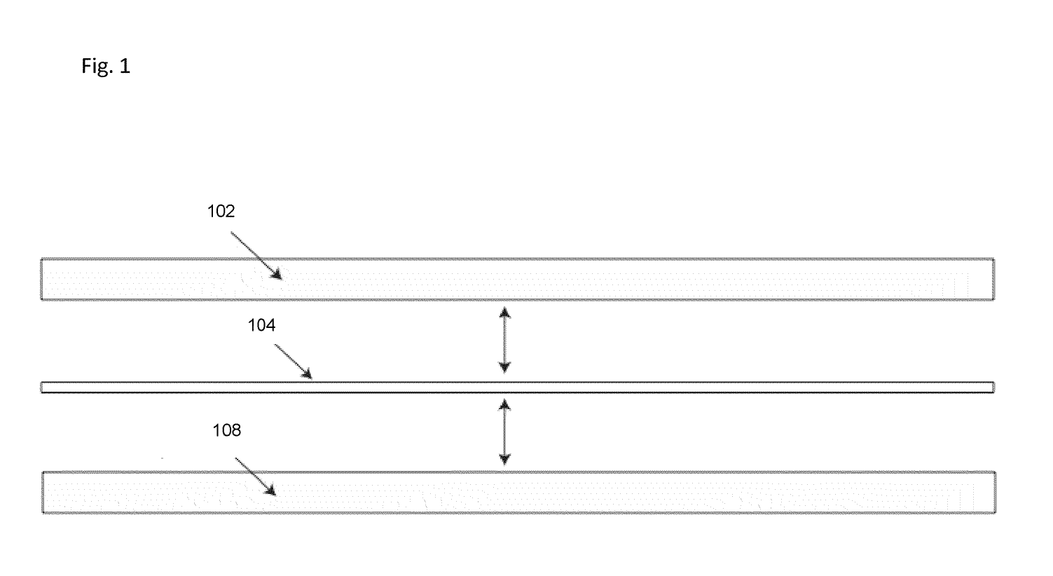

The present invention describes a photoelectric power producing facility, such as integrated with another structure or as an independent structure. The optimization of cost yield within the photoelectric facility may be based on a shorter lifecycle than current solar technologies wherein the “wear” resistance of the non-chip components may be significantly shorter to achieve substantially lower cost across the environmental and operating parameters of “wear”. Referring to FIG. 1, wherein the cost yield optimization may separate out the components into ‘expensive’, such as the photo reactive materials, and less-expensive′ into modular elements, such as a polymer matrix, categories wherein either the whole or a portion of the solar facility may be replaced in the short term due to wear and the expensive components may be resurfaced, recovered, or reconditioned thereby amortizing their initial manufacturing and installation cost over multiple facility life-spans. For example, a first layer 102 may be a polymer sheet (exposed) with 3-5 year environmental wear lifecycle, a second layer 104 a power producing sheet (protected) with a 75 year chip lifecycle, and a third layer 108 a polymer sheet (protected) with a 10-15 year environmental wear lifecycle. Additionally the less-expensive “worn” material may be recycled either on-site or off-site thereby amortizing their initial and recycling expense over multiple facility life spans. The photoelectric power producing facility may have modular elements which may focus, concentrate, and the like incident sunlight with or without an active or passive tracking facility and which may be installed and de-installed in whole or in part on a basis that may be determined by the individual lifetime characteristics on the components, by parameters set by market forces, and the like within the cost constraints imposed by the components or by a combination thereof. The facility may be designed in such a way as to optimize the market parameter as characterized by the initial cost and time period commitment to component material relationship and said components material characteristics such that a particular component may utilize a less “wear” resistant and less expensive material or structure to provide a more optimal cost to yield to installation time period commitment ratio.

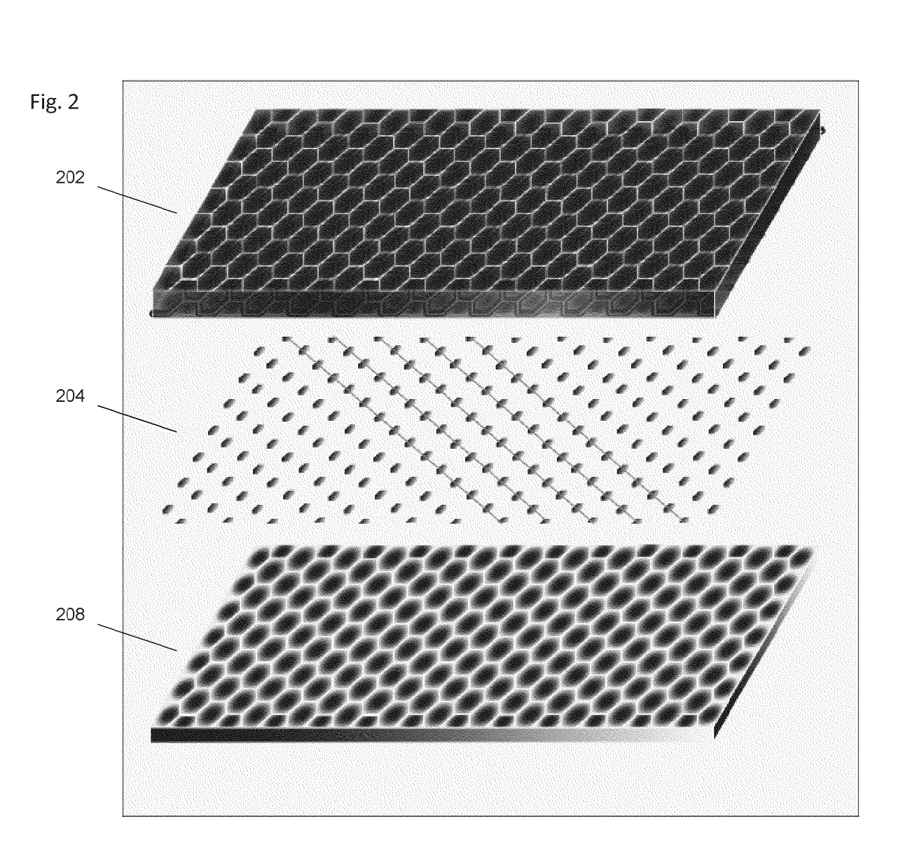

With regard to FIG. 2, the power producing facility may be comprised at its most basic level of a focusing or concentrating component 202, a containment component 208, and a power production component 204, wherein the power producing facility may also include transfer components, storage components, and the like, or a combination thereof. The power production facility may be a photoelectric conversion facility. It may also include a heat sink, thermal power production, environment conditioning facility, and the like to dissipate excess heat produced by the system, utilize said heat for some other purpose such as power production, and the like as a whole or partial element of an environmental conditioning system, an HVAC system for example. A thermal system may in certain embodiments constitute the only power producing system or may be combined with a primary photoelectric system. Such a system may use any elements that are known in the art to make productive use of the excess thermal energy produced by a solar system including but not limited to a thermal differential system (similar to geothermal systems), a cogeneration system, a desiccation system, and the like. Material differences between the concentrating element and the containment element may be utilized in order to enhance the internal reflection within the containment unit.

The power producing facility may also be designed wherein the overriding design principles and parameters may be determined by optimization of the modularity of components based on the environmental “wear” characteristics, the expense of the individual components, and the installation and de-installation cost of said components relative to the overall yield of the system.

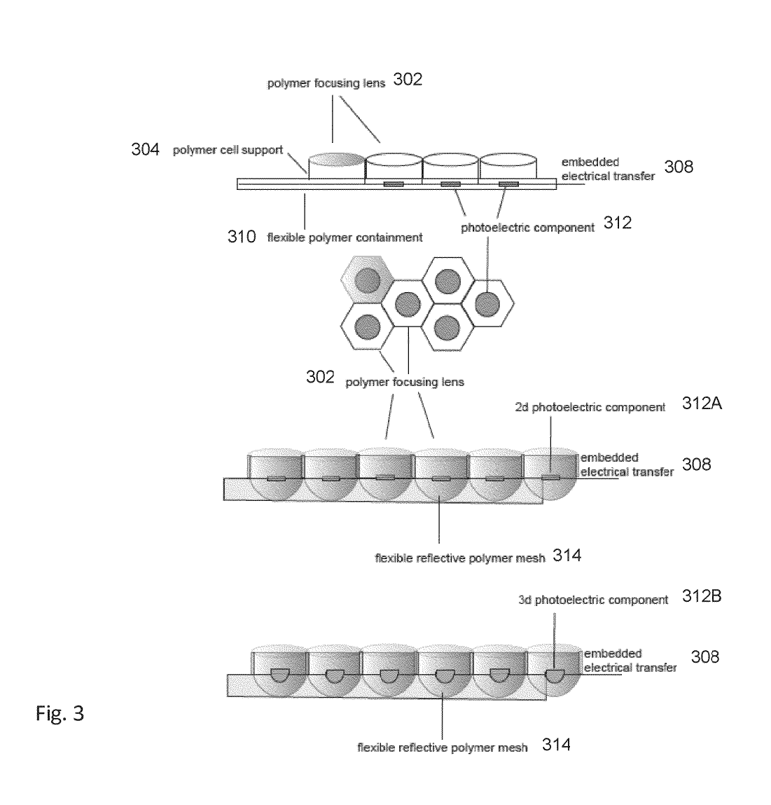

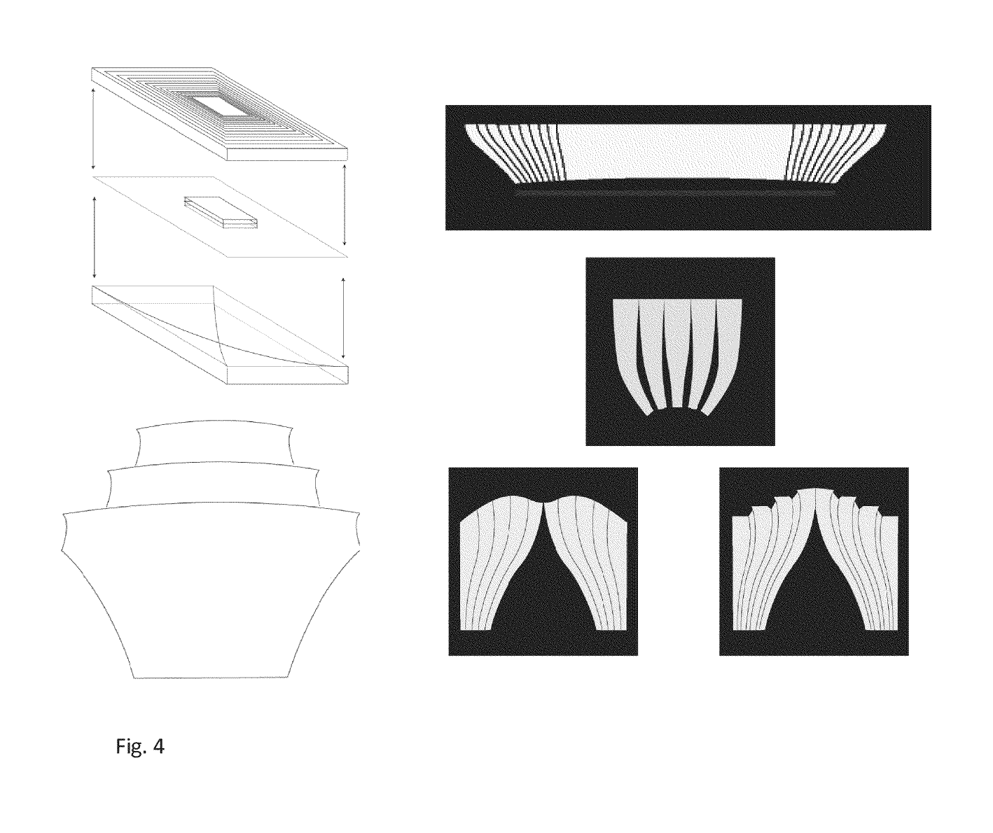

Referring to FIG. 3, the power producing facility may be comprised of a flexible, rigid, and the like polymer; a fixed, embedded, and the like array of polygonal polymer cells comprised of a single or plurality of concentrator facilities; an inverted reflecting facility whereby light captured by the photoelectric material may be maximized; and the like. For example, and depicted in FIG. 3, the power producing facility may be made up of polymer focusing lenses 302 on a polymer cell support 304 with photoelectric components 312 and embedded electric transfer 308. In embodiments, the photoelectric component may be a 2D photoelectric component 312A, a 3D photoelectric component 312B, a linear photoelectrical component, and the like. The power producing facility may include a reflective surface, such as a flexible reflective polymer mesh, and the like. The photoelectric material may be embedded, suspended, and the like within the polymer cell. In this regard the photoelectric component may be a singular, layered flat, substantially 2-dimensional component geometry, of a variable or 3-dimensional geometry, and the like to maximize the power derived from the cell geometry. This may include a spherical surface, semi-spherical, polyhedral surfaces, and the like, or a combination thereof. This may allow production of photoelectrical components directly by methods such as seed deposition, deposition, spray coating, and/or molding, and the like, rather than machining. The photoelectric component may be any of the class of photoactive materials such as crystals, polymers, photoreactive surficants, and the like. The interior of the polymer cell may be infused with a fluid that in certain instances may achieve lasing or near lasing conditions that may be contained within the cell or output to a secondary energy conversion facility, such as a coherent single frequency or multi frequency input.

The concentrator may be of variable surface geometry to maximize incident light. The concentrator may be formed of a concentrating fiber optic material. The inverted reflective surface may be applied to an optimal geometry that maximizes incident light reflection to a photoelectric surface. The photoelectric surface may be comprised of multiple surfaces in three dimensions. The components of the sheet may include embedded or external capacitors or storage devices to normalize or offset power on a time basis system output.

The concentrator may be of variable surface geometry to maximize incident light. The concentrator may be a formed of a concentrating fiber optic material. The inverted reflective surface may be applied to an optimal geometry that maximizes incident light reflection to a photoelectric surface. The photoelectric surface may be comprised of multiple surfaces in three dimensions. The components of the sheet may include embedded, external capacitors, storage devices, and the like, to normalize or offset power on a time basis system output.

The solar sheet may be formed or molded to mimic a substructure surface, such as roofing shingles to appear substantially the same and provide temporary environmental wear protection to the substructure surface in addition to power output.

In embodiments, the cells of the solar facility may be suspended in a flexible polymer matrix material which may have reflective properties directly incorporated and may include a power gathering, storing (such as ferroelectric polymer-based capacitors), distribution mechanism, and the like.

In embodiments, a power producing “cell” may be comprised of a capsule where in the exposed portion is a concentrator and interior portion is reflective with at least one of a plurality of inorganic or organic power converting components suspended in the capsule. Light captured by the concentrator may be transferred internally by the geometry and surface properties of the capsule/cell. The concentrator upper surface may be comprised of an attenuating-concentrating fiber optic array that may be glass or a polymer having minimal reflective properties. The surface of the concentrator may cover the optimal light gathering curvature and the exit of the fiber optic components may cover a fraction of the interior surface area, preferably convex in shape, and the remainder of the interior surface may be reflective such that a large portion of the interior surface reflects the photons back into the interior of the cell to maximize interaction with the power producing element/s.

In embodiments, a power-producing cell may be comprised of a capsule wherein in the exposed portion is a concentrator and interior portion is reflective with an inorganic or organic power converting component suspended in the capsule. The concentrator and interior of the cell may be comprised of multiple layers/geometries of materials with different refractions indices such that the photons of the incident light are channeled to a or a plurality of power producing elements, such as an organic or inorganic chip, to maximize the concentration and energy gain of the cell. The cell may further have its non-exposed perimeter coated with a reflective coating to maximize photon interaction with the power producing element(s).

In embodiments, a power-producing cell may be comprised of a capsule wherein in the exposed portion is a concentrator and interior portion is reflective with an inorganic or organic power converting component suspended in the capsule. The concentrator of the cell may be prismatic such that the concentrator concentrates the incident light and separates said light into its component frequencies, focusing said frequencies onto specific areas of the cell interior. The power producing component(s) are comprised of multiple materials geometrically arranged such that the materials occupying a specific area to optimize power conversion for a specific band or frequency of the incident light. This may include dye-doped, crystal, organic chips, and the like.

In embodiments, the flexible substrate may form the lower reflective surface and the substrate may be covered by a flexible upper sheet of concentrators. The power producing element may be three-dimensional or inverted such that the light is directed by a concentrator array to the reflective surface and then concentrated by the reflective surface such that the absorption from the sun does not vary the area of concentration as the sun moves across the sky.

A convex reflective surface may form the upper surface wherein a concentrator is situated at the center of a convex “bowl” such that the concentrator transfers the light internally to the periphery of the cell and thereby to the reflector at the base of the cell.

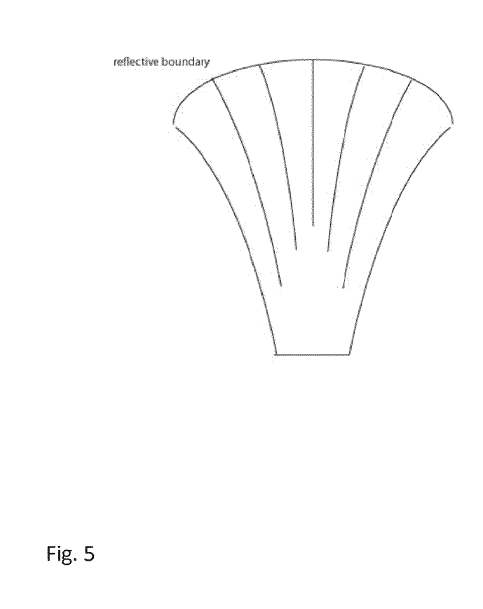

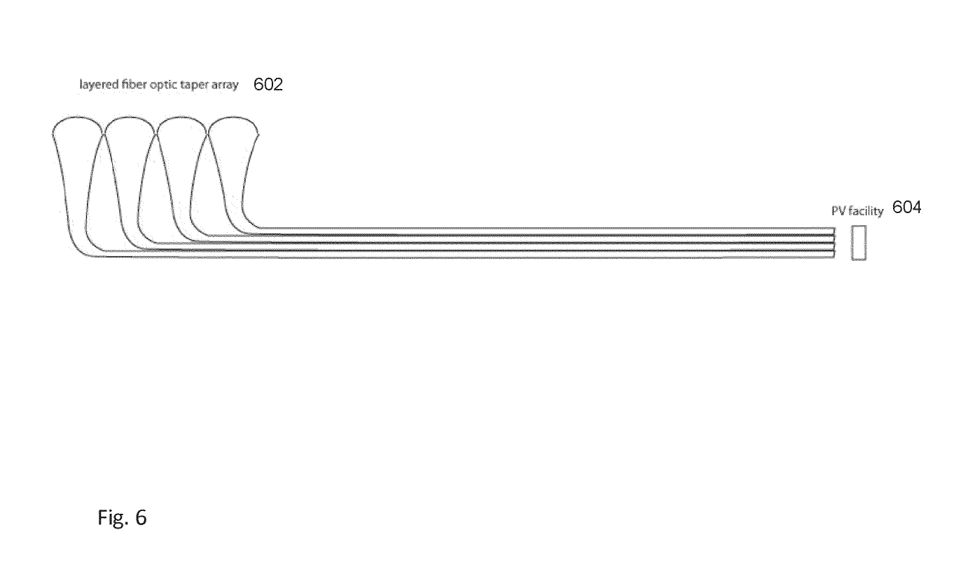

The surface of the concentrator may be shaped to maximize refraction to the interior in low incident angle light. Where the concentrator may be a convex ellipsoid, a concave convex ellipsoid, a stepped structure similar to a ziggurat shape that maximizes internal refraction of high-angle and low angle incident light, and the like. The upper portion of the stepped profile may provide a surface substantially orthogonal either curved or flat to high angle incident light and constitutes a focusing element to the next step such that the vertical portion is curved or angled to maximize low incident light exposure. This may be comprised of a converging upper portion and a diverging lower portion, such as shown in FIG. 4. The concentrator may be comprised of separate focusing layers where the each layer is reflective and curved to channel light to the interior portion of the concentrator, such as shown in FIG. 5. An array of layered fiber optic taper 602 may be used to concentrate incident light and direct said light to a central facility comprised of a PV material 604, such as shown in FIG. 6. In embodiments, a fiber optic taper may be linear or cellular.

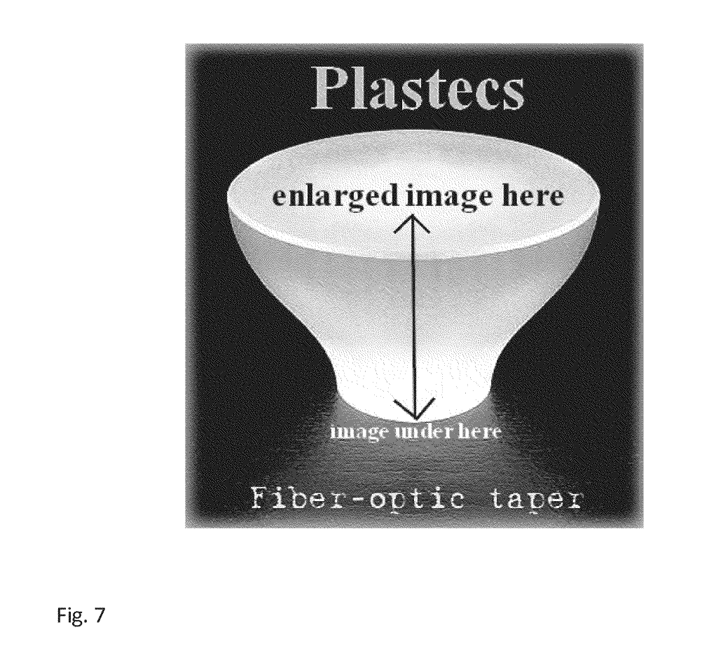

In an example, a fiber optic plug is shown in FIG. 7. Here, the top of this plug is 0.44 cm diameter, the bottom is 0.19 cm diameter, and the area difference is 0.28 cm̂2. Invert the lesser area geometry to an exterior boundary annular ring and the inner diameter of the annular ring is 0.4 at same area difference. Curve the top convexly or some more complex geometry to create higher capture from incidental light. Curve inside the annularity concavely, coat with a mirror coating, attach to a concave mirrored substrate, and you get the schematic below the taper image. This configuration may perform well for concentrating the light onto a smaller and therefore cheaper chip and of capturing a high percentage of the light as a kind of pseudo-pump. In embodiments, this configuration may achieve lasing, although in embodiments, lasing may be avoided due to associated thermal issues. Another possibility may be to turn it into a solar pumped micro laser if possible and put the chip at the laser exit or even make the laser exit a fiberoptic cable that transfers the light to some centralized conversion facility. In that regard one could even use prismatic fiberoptic ends or single prism at the centralized facility to separate the light into component frequencies matched to an optimally doped crystal gradient to convert the power of the given spectrum avoiding the entire problem of losing efficiency in certain frequencies with any singular doped crystal type (e.g. better at the blue or red ends). The light in the fiber network could also be further concentrated at the central facility by using tapered ends. In embodiments, the system may also use the thermal byproducts to produce more power.

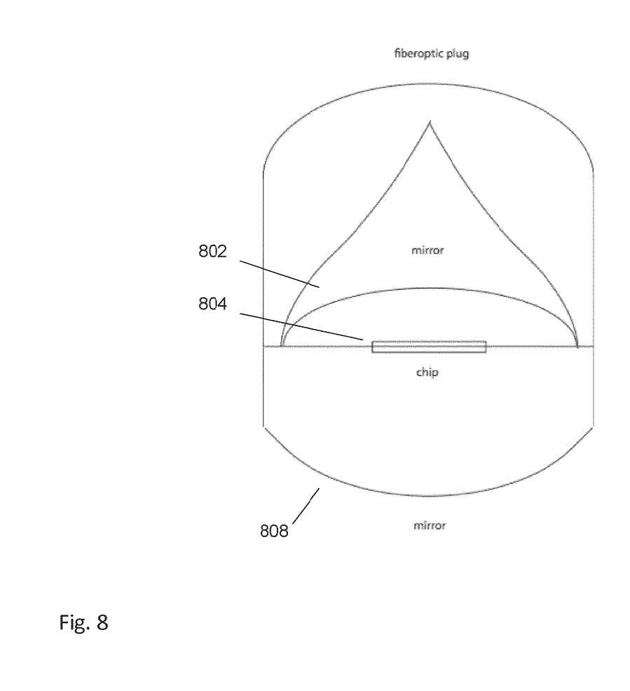

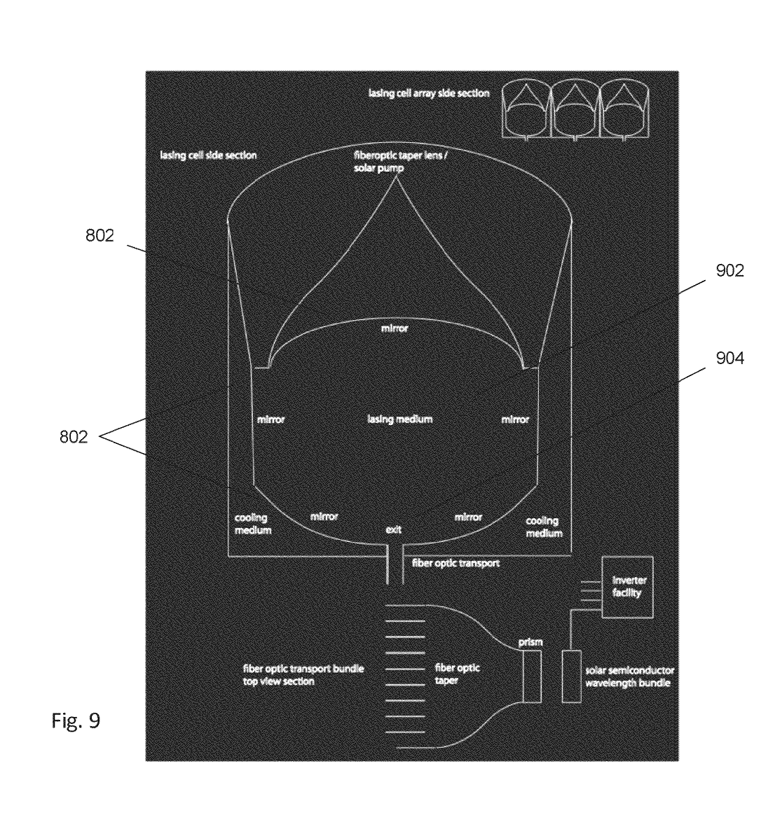

FIGS. 8 and 9 show embodiments of fiber optic transfer to a central facility. These may be done a number of ways. For instance, there may be a chip 804 within cell and at the central facility, with mirror components 802. Chips may be just at the central facility. The cell may be structured with a lasing material 902 if it is possible to build up the energy potential in the cell, or it may just concentrate the light into the exit 904. The chip as illustrated may be a chip comprised of subsections of crystals that are optimally doped for a particular wavelength conversion, or it may be a singular crystal.

In embodiments, the fiber optic taper may be used to control the input angle of the light. This may allow granular control on the containment on a time basis by faceting the surface of the reflectors such that the path the light would describe in the cell would be predictable. This may have advantages over a normal reflector, even with azimuth control.

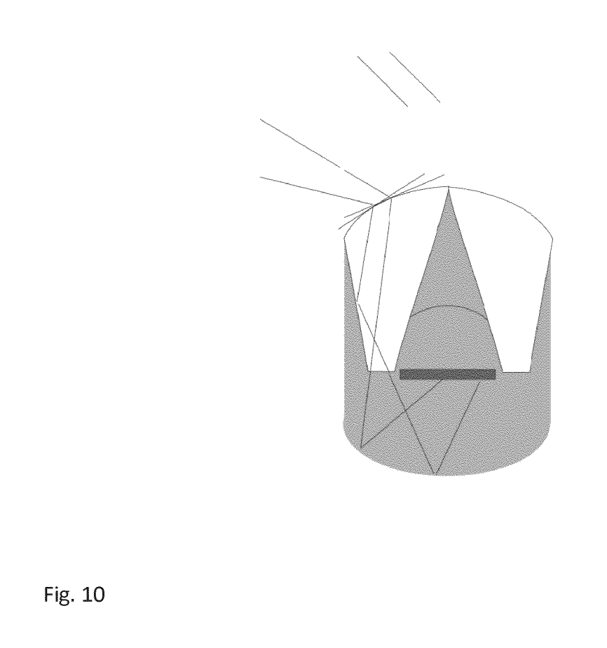

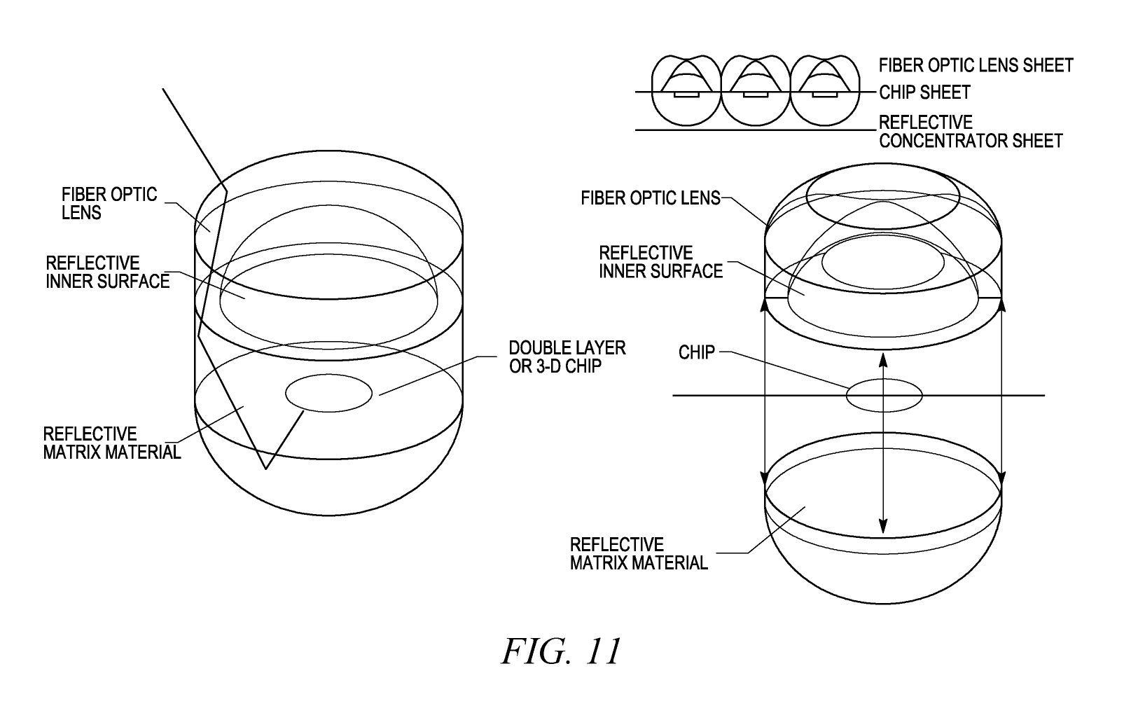

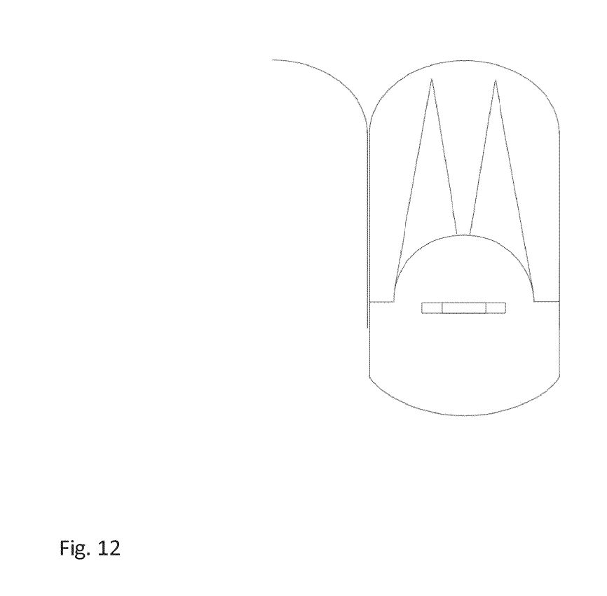

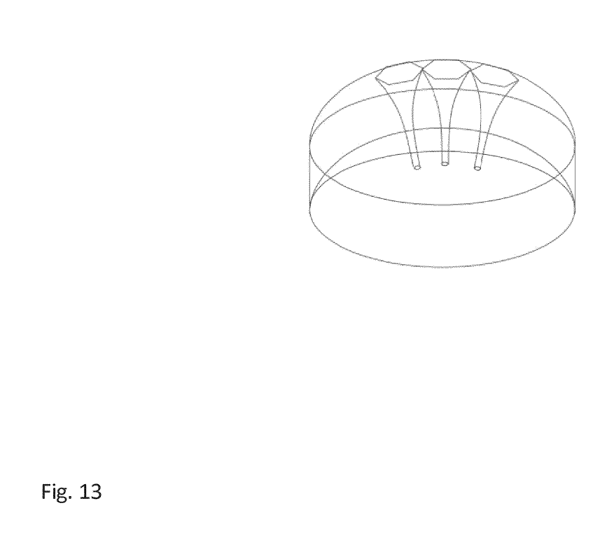

In embodiments, various cell configurations may be utilized, such as provided in FIGS. 10-13.

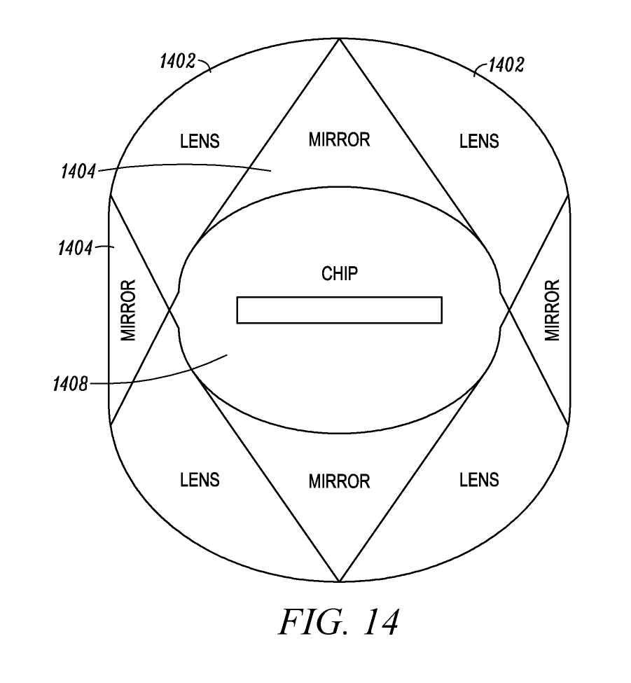

In embodiments, a cell may have a plurality of input fiber optic concentrator/taper structures feeding in from the perimeter geometry, thereby creating angular input efficiency without utilizing active tracking to maximize capture at varying angles. In embodiments, FIG. 14 shows a cross-section of a dual input cylindrical concentrator system that may be executed as an upright structure, such as including lens 1402 and mirror 1404 components with an embedded PV chip 1408. These concentrator types may be cylindrical or any polygonal geometry that maximizes input to the core chip. They may be executed as vertical or horizontal structures wherein the exposure of a “core” conversion mechanism may be maximized on a daily basis without utilization of a tracking mechanism. The polygonal concentrator fascia may channel light toward the core mechanism and face exposure geometry may be optimized by calculating a maximum geometric exposure across the input arcs. This geometry may be convex, concave, or a combination thereof.

In embodiments, the interior surface may be coated directly with a photo-reactive surface such as through thin film deposition such that the interior of the cell may form the power producing facility, where interior surfaces may also include reflective surfaces. This may, such as with an inexpensive deposition or coating method, produce substantially more power from the light in the cell as the light is reflected interiorly and the surface interaction is substantially increased by the interior geometry relative to the upper concentrator incident surface. To this goal the interior surface of the cell may be non-uniform, e.g. polyhedral features extending from the mean interior curvature, to increase the effective surface area.

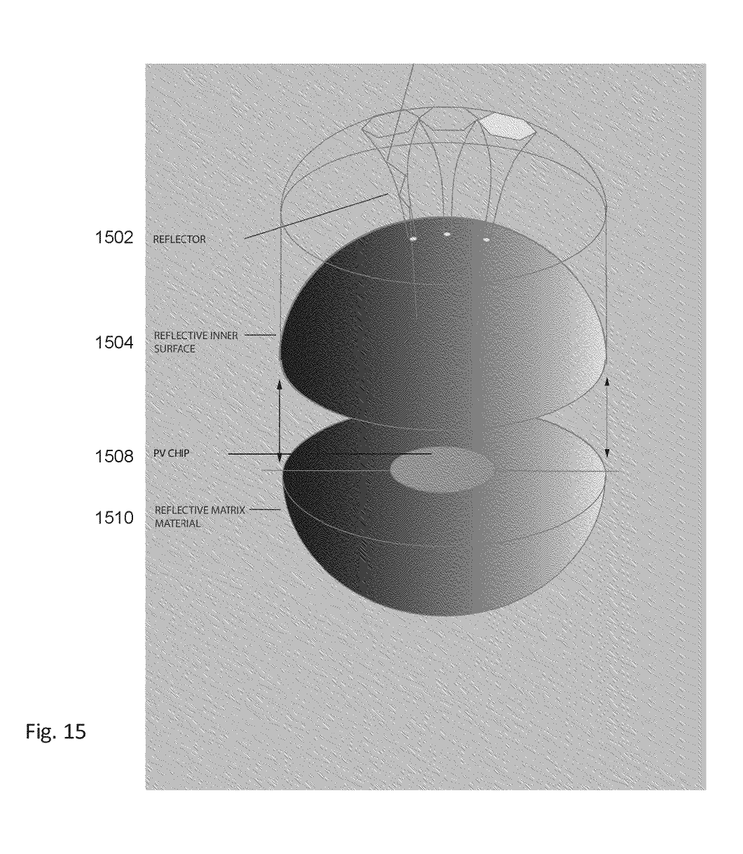

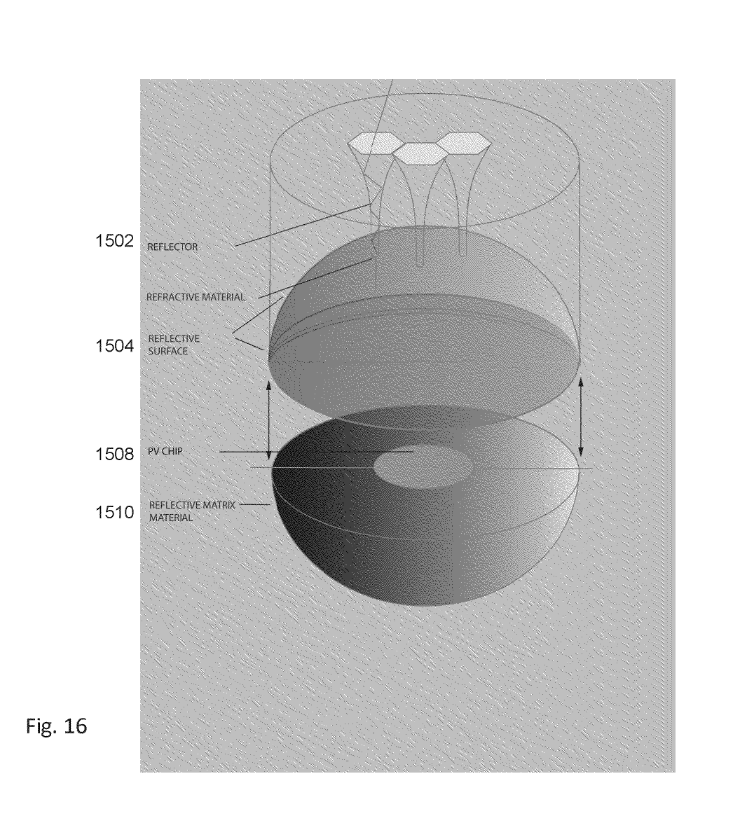

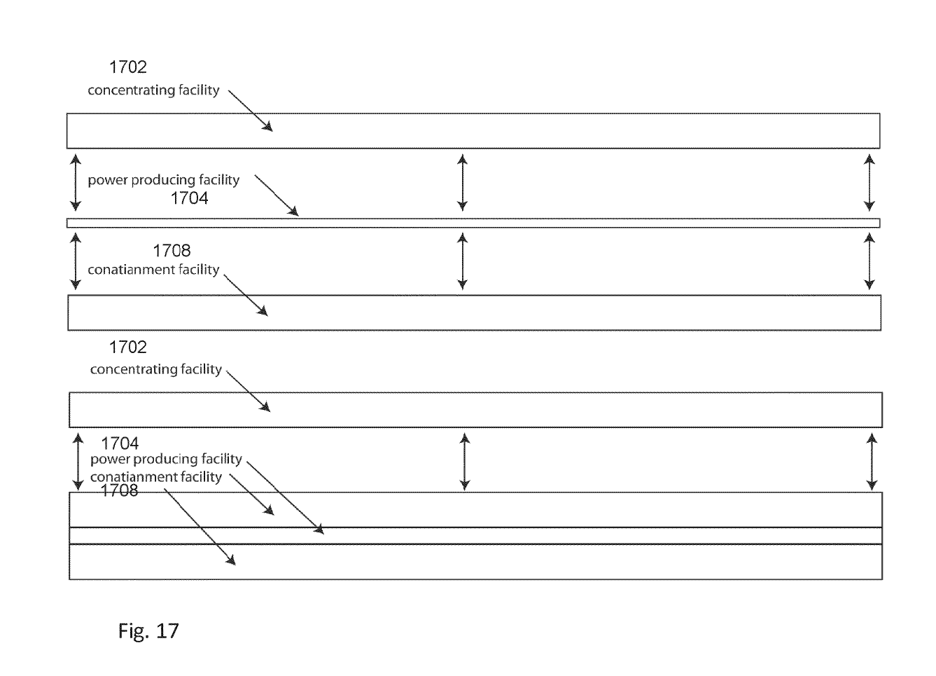

Referring to FIGS. 15 and 16, in a preferred embodiment a concentrating element may channel light through a waveguide into a containment element wherein the output area of the waveguide is smaller than input area and the containment element may be bounded by the projected incident input area, some specified larger area, and the like, and be reflective, refractive, and the like or some combination thereof in order to contain the input light and may be designed to minimize the amount of light that reflects back out of the containment element either through reflection, refraction, and the like elements or a combination thereof. In figures, various reflecting surfaces 1502, 1504, 1508 are shown, aiding in the concentration of light to the PV chip 1508. A conversion element such as a crystalline PV chip, PV film, and the like may be suspended or embedded within the containment element in such a way that over the course of multiple reflections the contained light may be likely to be wholly or mostly absorbed by the PV element allowing a higher effective “concentration” ratio than may be produced by the concentrating element alone. This may produce the additional benefit of the contained light having multiple “passes” at the PV element as in each pass only a portion of the photons will dislodge electrons at the P/N junctions and thereby may result in an overall increase in the efficiency of the system. The concentrating and containment elements may be executed as cylindrical, linear, and the like, polygonal elements, spherical, three dimensional polygonal elements, and the like or a combination thereof based on an optimal cost to configuration to concentration to chip size to yield ratio.

The concentrating, containment, and power production elements may be individual modules such as typical solar modules, may be formed to duplicate any appearance such as roof tiles or may be formed in sheets wherein the sheets may molded and assembled individually and then installed in place atop a structure or substrate, and the like. Sheets, module elements, and the like may have “quick” connect elements that allow them to be installed and de-installed quickly and at low cost. Sheets may additionally be installed as a singular molded sheet wherein separation and reconditioning, refurbishing, recycling, and the like of the various sheet components may occur on site or off site.

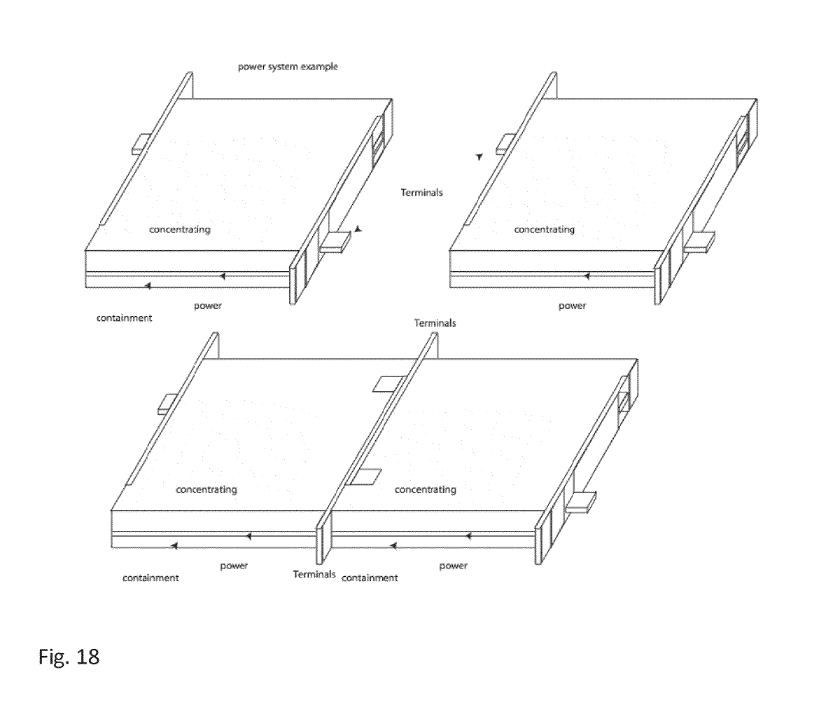

In a preferred embodiment the lowest layer may clip into a structure, be adhered to a substrate, be partially formed of a high friction material that would hold the sheet in place on a given substrate such as a roof, and the like or any combination thereof. The topmost sheet may be a polymer sheet formed by methods common, uncommon, and the like in the art such as thermo-molding, injection molding, stamping, 3-d printing and the like that may “snap” or be attached into a second power producing sheet that in turn may “snap”, be attached into the lowermost sheet, and the like. Attachments between sheets may be by means of any number of attachments such as are known in the art such as clips, frames, screws, channels, and the like provided that said attachment mechanism may minimize the time and cost necessary to install the system. As depicted in FIG. 17, the upper concentrating sheet 1702 may be comprised of concentrator, reflector elements, and the like, a combination of the two molded into a single polymer sheet, assembled from multiple component sheets such as the combination of a polymer concentrator sheet with a metal stamped wave guide reflector sheet with a third sheet comprising the upper elements of the containment unit, and the like. The power producing sheet 1704 may be comprised of a “net” of power producing elements such as PV chips that may be connected by power transfer elements such as conductors and main transfer cables. Said net may be a loose net wherein the areas between the chips and the conductors connecting them may be empty or the entire assembly may be embedded within a polymer sheet wherein the chip portion of the assembly may or may not be exposed. The lowermost sheet may be the lower portion of the containment 1708 wherein the sheet may be comprised of a reflective polymer sheet, multiple component sheets, and the like, and then assembled the upper and lower sheets may “sandwich” the power producing sheet between them such that the lower portion of the upper sheet and the lower sheet may then form the containment element with the power producing elements contained therein and protect the power producing sheet from environmental exposure allowing its reuse in situ or upon de-installation. The power producing and containment facilities may also be produced and installed as a single sheet wherein the environmental exposure of such a sheets may be limited by the upper concentrating sheet, a bounding structure, and the like.

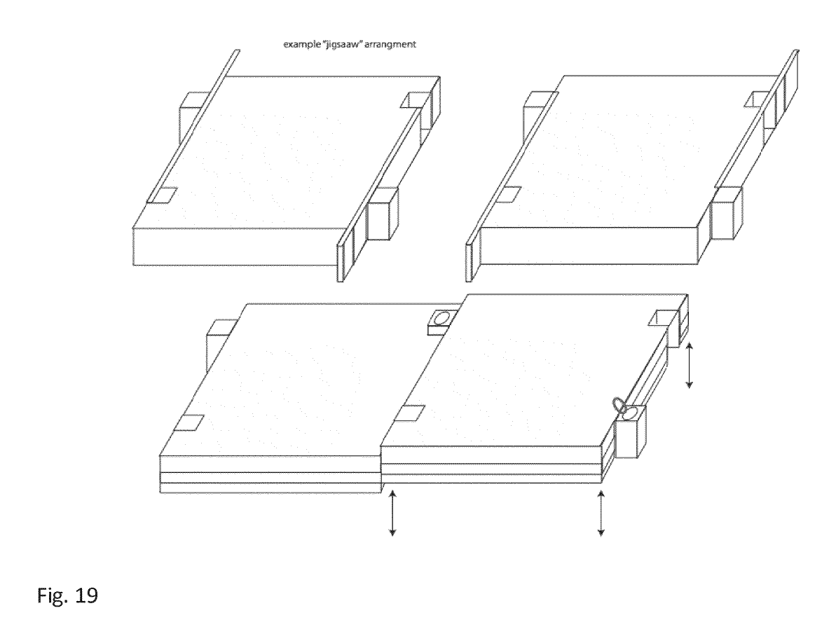

In a preferred embodiment the concentrating, containment, and power producing elements may be formed into a self-contained module, FIG. 18, that may be designed to connect as a “plug and play” element into a larger array of modules. The characteristics of the elements may be largely similar to the sheets described above but bounded by a modular shape instead of being formed and installed as sheets. In some embodiments it may be preferable that only the power producing or lower elements be formed in this way with an integrated installation structure and covered with an upper contiguous sheet. It may be preferable that all elements are formed in this way. In all embodiments it is desirable, but not necessary, that the less expensive shorter lifetime materials constitute the exposed portions of the module and the more expensive components be completely enclosed by said elements. In this regard a typical framing structure may be acceptable but an optimal configuration is a module version of the “snapped” sandwiched structure described above with all of the attendant in-situ, on-site, and off-site parameters described above. Referring to FIG. 19, module edges and power transfer connectors may be formed as “puzzle” elements such that the individual modules may be independently removed from an array without the array or portions thereof having to be disassembled and which may allow the most optimal protection to the non-recycled elements of the system.

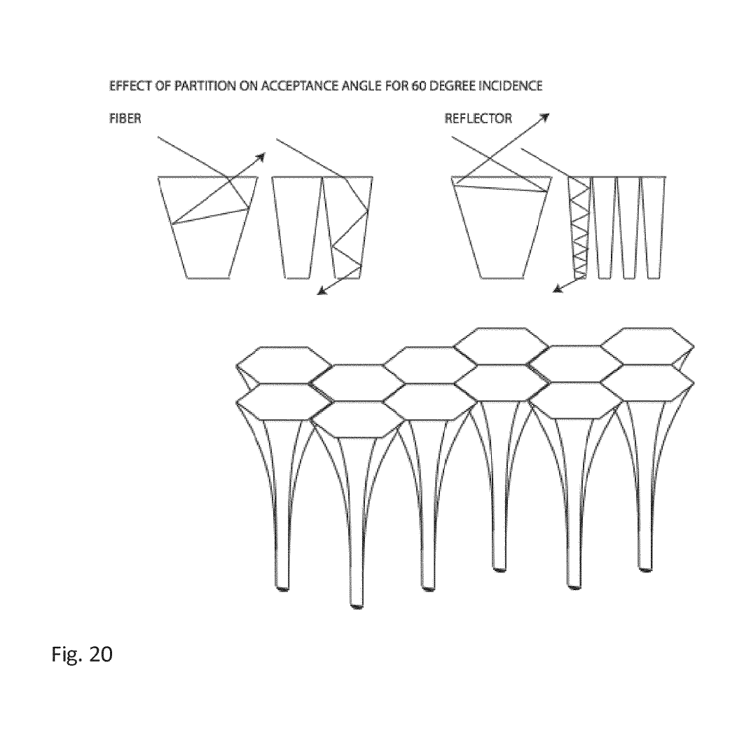

The focusing, concentrating, and the like facility may be comprised of a concentrator, optical taper, reflector, refractive facility, and the like or any combination thereof with the purpose to concentrate light from an incident input area to a smaller output area for input into the containment element. The concentrating facility may or may not include some active or passive tracking capability. The concentrating element may be formed by a fiber optic taper, concentrator, a reflecting element, and the like or a combination thereof which may be partitioned into an array of grouped, separated, and the like wave guide channels in such a way that may optimize the input angle of acceptance of the system as a whole. Referring to FIG. 20, partitioning of the concentrating element with an optimized incident and waveguide geometry may substantially increase the angle of acceptance and achievable concentration ratio compared to a unibody or singular concentrating element, such as a fiber optic taper or simple or compound concentrator, before light is reflected back out of the concentrating element while simultaneously avoiding the tracking expense associated with focusing systems. Each partitioning in the waveguide array either globally (over the whole concentrating element) or locally (within a given waveguide or set of waveguides) or both, e.g. an increase in the number of elements in the array while the input and output areas and their ratio remains constant, may allow the angle of acceptance to increase as the initial reflectance/refractance angle within a given wave guide element decreases with each partition wherein the acceptance angle to cost complexity ratio is optimized based on cost to concentration yield parameters of the concentrator. The interior portion of the concentrating element may constitute an element of the containment unit wherein the interstitial difference between the larger input area projected around the smaller output area may be formed of a reflective material and the output areas themselves may be geometrically arranged or formed to maximize the interior reflection/refraction of the contained light. A partitioned array may guide the light into the containment element exteriorly annularly, interior annularly, and the like or some combination thereof or output may be uniformly or non-uniformly distributed over the inner surface.

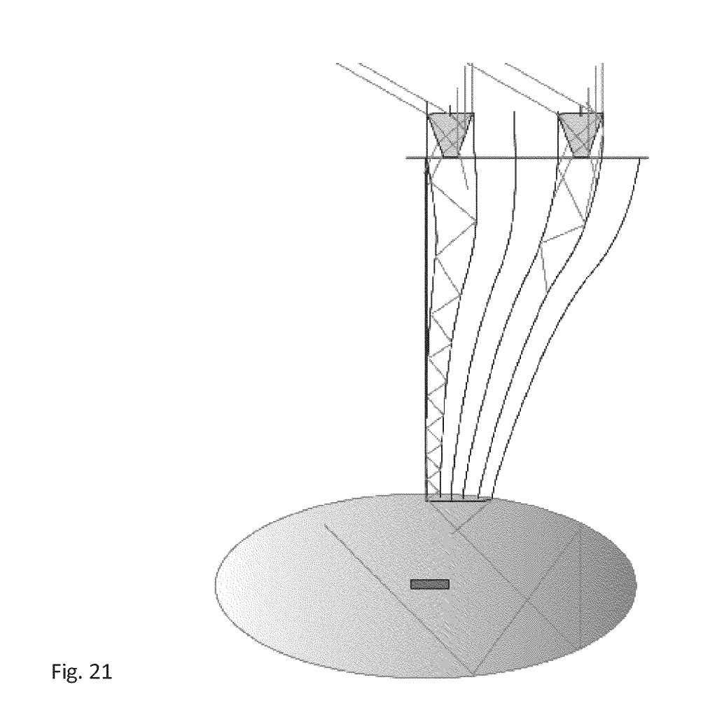

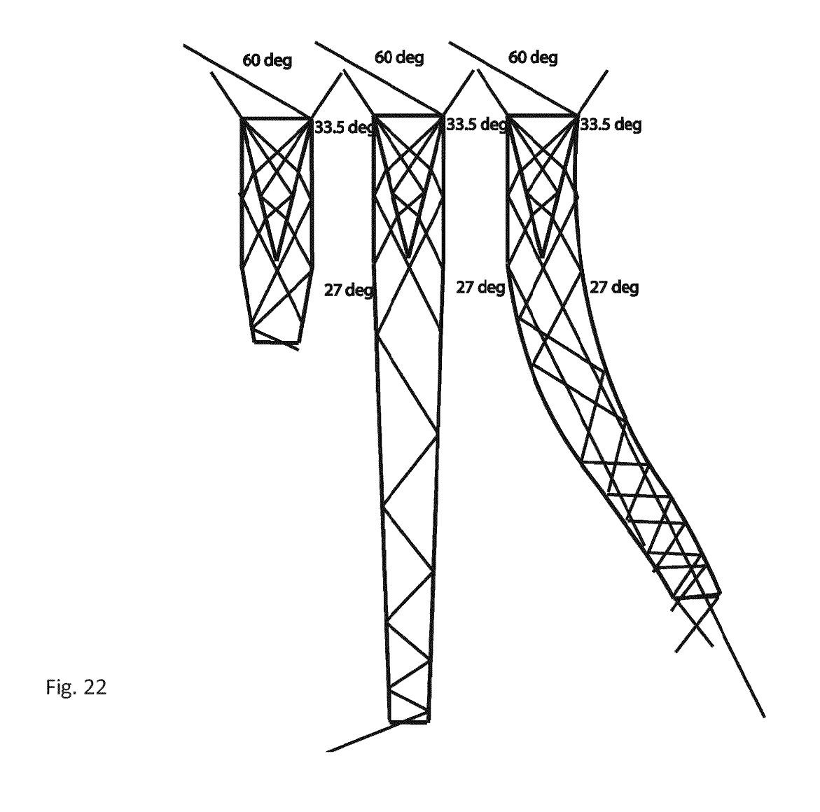

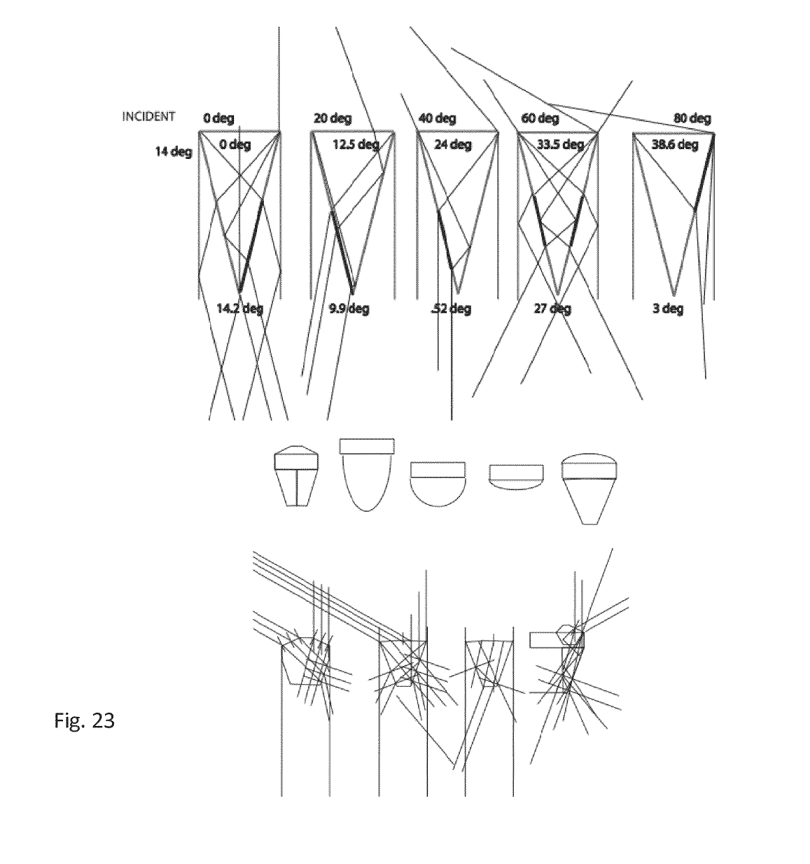

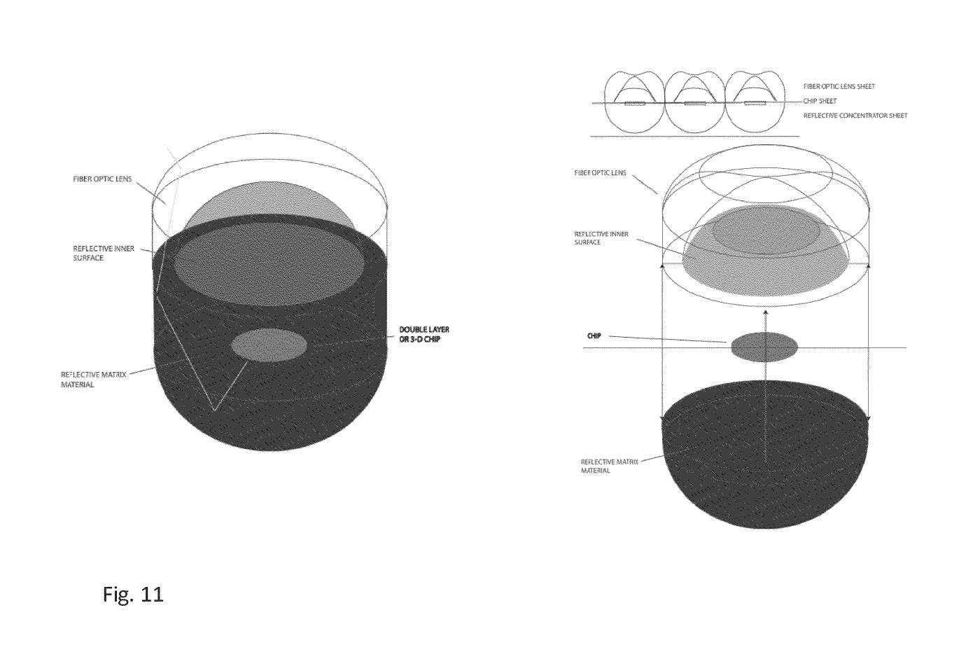

Referring to FIGS. 21-23, in a preferred embodiment the concentrating element may be comprised of an array of taper element, singular or compound, and an array of reflecting elements wherein the taper may constitute the first stage of a compound wave guide and be the shape of an inverted triangular solid, cone in the case of a uniformly annular element, distributed element, an inverted triangular solid in the case where a linear execution is preferred, and the like, and the reflecting element may constitute a second stage of a waveguide that may be executed similarly as an annular, distributed, linear, and the like element or some combination thereof. The upper or incident surface of the taper element may be flat, of variable geometry wherein the geometry of the upper surface and its relation to the partitioning of the waveguide may lead to an optimal incident surface area ratio, and the like. This geometry may include a smoothly curved surface, a polygonal surface, a dimensionally partitioned surface similar to a Ziggurat form, and the like. In the case of a flat or variable upper surface each annular first stage element may be designed to produce an optimal mean output angle based on the range of incident input angles or arc for which it is designed wherein the optimal values may be determined by the acceptance properties of the secondary element of the wave guide and wherein the mean output angle into the secondary element may be entrain 100% of the incident light into the secondary element. According to optical models of said embodiment a primary element wherein the lower walls were 10-20 degrees off normal may be optimal to achieve the best output range for the secondary stage over an incident input arc of 160 degrees. This element may in combination with the reflecting stage channel light into the containment element at a substantially higher concentration ratio than a single stage concentrator. For example a maximum initial input angle into a flat surface over an arc of 160 degrees may be 38 degrees, post refraction, for fiber waveguide or 60 degrees for a reflector waveguide whereas a maximum input angle into a reflective waveguide after using a first stage 14 degree simple fiber optic element may be 27 degrees. This structure may additionally avoid the necessary use of singular polymer concentrator and containment elements to avoid internal reflection at the output of a fiber concentrator into a lower indexed medium. The compound concentrator also may use substantially less material than a uniformly fiber concentrator.

In another preferred embodiment a single stage concentrator may be used wherein the wave guide may be a partitioned fiber optic taper, a partitioned reflector, or the like wherein the incident light is guided directly to the containment unit such that the incident angle to the containment element is sufficiently acute to ensure entrainment in the event that the containment element is comprised of a different material than the concentrating element.

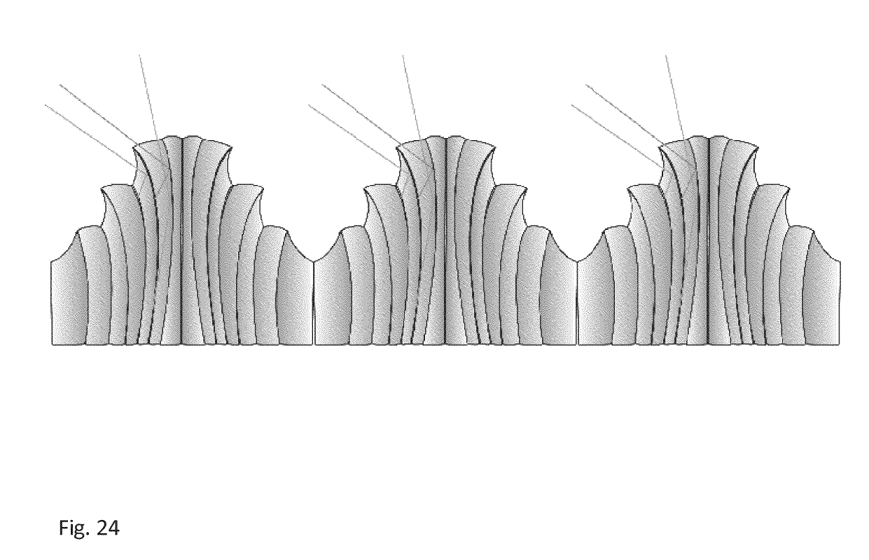

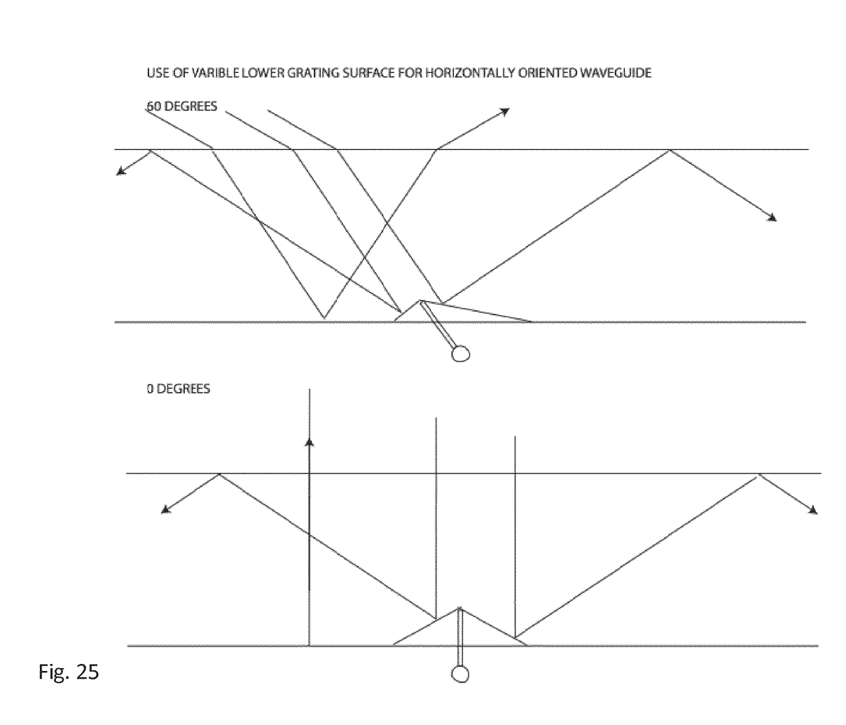

In another embodiment, FIG. 24, a variable surface, stacked surface, and the like may be used as a horizontal wave guide wherein the surface may be formed of layered tapers and wave guides, may be arranged in such a way to increase, make constant the incident surface area at any given incident angle, and the like, similar in some ways to the inversion of the Fresnel concentrator principle, and an internal refractive angle to maximize the amount of light trapped in the wave guide. The form may include the upper surface, the lower surface, compound surfaces, and the like and may also include active or passive means to combine reflectors with the wave guide medium to maximize the light contained within the waveguide based on the incident input angle. An example may be utilizing a contained liquid as a wave guide medium wherein the lower surface and the containment material serves as adjustable reflectors either internal or external to the wave guide medium that reflect the input light in such a way to create substantial internal reflectance on the upper surface of the waveguide. Referring to FIG. 25, such a system externally may be achieved with flexible waveguide materials such polymers, gels, and the like and a simple motor system, thermally reactive system, and the like. In both the taper and shaped waveguide embodiments the power conversion surface would be at the horizontal boundaries of the particular implementation be it a sheet, modular panel, and the like or some combination thereof. Additionally such an embodiment may utilize a “grating” reflector structure either with or without a refractive fluid. A lower reflective surface, such as a fixed grating surface, may also move independently of the upper surface horizontally, vertically, and the like or a combination thereof based on the initial incidence angle to maximize refracted light within the waveguide. The length of the waveguide desired in a particular implementation may be determined by the ratio of the height of the grating/reflective surface to the depth of the waveguide medium. This embodiment may or may not use a containment system dependent on a particular implementation and may include a means of thermal energy capture from the operative medium.

All embodiments and descriptions above may be used combinatively. For example a partitioned reflector waveguide upper surface may be used in combination with a variable grating lower surface and an interstitial medium to affect a horizontally oriented concentrator pair wherein the refractive index of the medium may engender the containment through internal reflection.

In embodiments the concentrator or taper element, be it singular or a stage, of a partitioned array assembly may be made of various fiber optically suitable materials such as acrylonitrile butadiene styrene (ABS), polycarbonates (PC), polyamides (PA), polybutylene terephthalate (PBT), polyethylene terephthalate (PET), polyphenylene oxide (PPO), polysulphone (PSU), polyetherketone (PEK), polyetheretherketone (PEEK), polyimides, polyethylene, polypropylene, polystyrene, polyvinyl chloride, polymethyl methacrylate, polyethylene terephthalate, and the like, various types of glass, transparent alloys, and the like, and may be molded, cut, formed and the like by methods known in the art. The reflective or refractive element, be it singular or a stage, of the concentrator may be made of metallic, polymer, composite and the like, such as but not limited to ceramics, reflective materials such as, but not limited to, all classes of polishable metals, reflective, surfacable polymers, reflective surfacable composites, and the like or any combination thereof. The reflective or refractive element may be made by common or uncommon methods as are known in the art including, but not limited to, thermo molding, injection molding, vacuum molding, casting, cutting, stamping, baking, and the like.

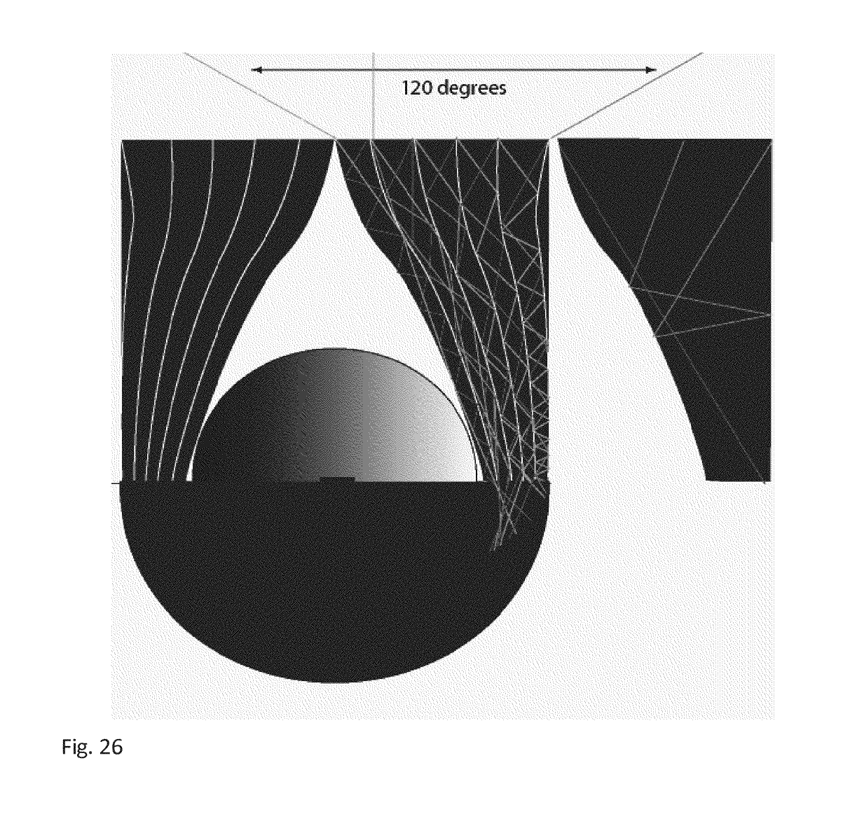

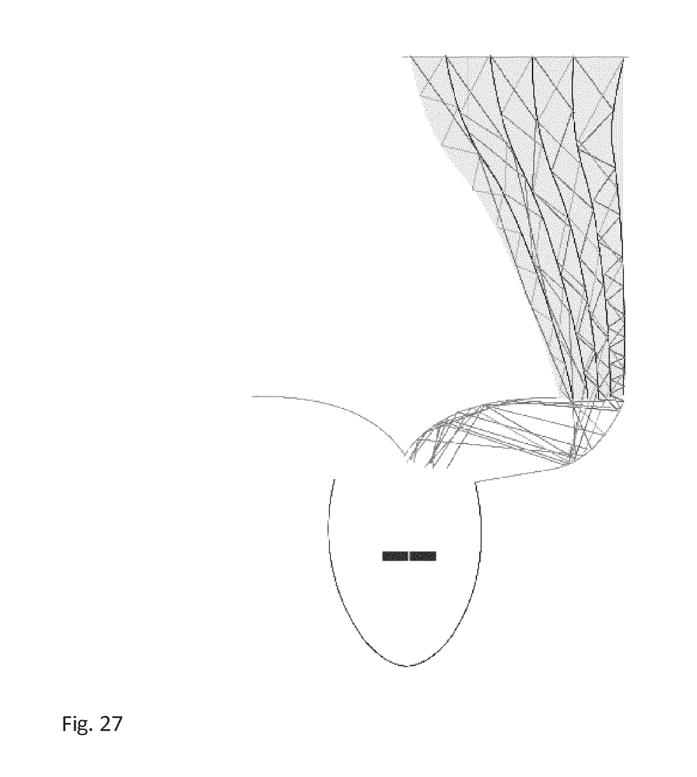

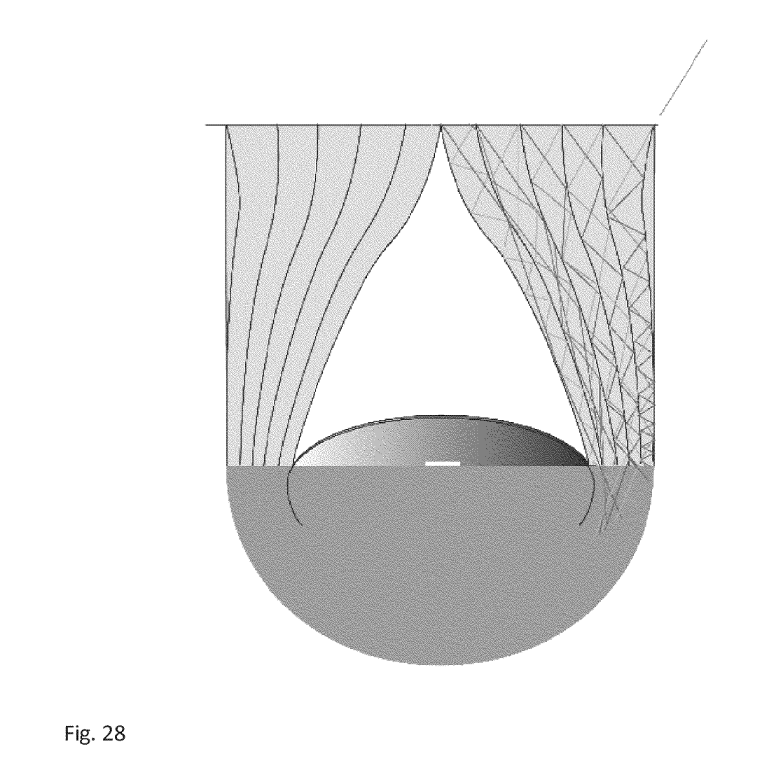

The containment facility may be comprised of a singular or plurality of interiorly reflective, refractive, and the like surfaces or a combination thereof, examples of which are given in FIGS. 26, 27, and 28. The facility may be uniform with respect to revolution around an axis, variable with respect to revolution around an axis, and the like, and may be curved, polygonal in nature, be singular, compound, and the like in terms of reflective or refractive stages with various stages being of the same or different materials to optimize internal reflection or refraction, may include an independent wave guide structure, and the like or a combination thereof. The facility may be globally circular, elliptical, polygonal, rectangular, and the like with respect to its global basis geometry, or a combination thereof. This facility may have a power producing element contained within it, may have an output channel, and the like to a power producing element or a combination thereof. Said contained power producing element or output channel may be vertically, horizontally, and the like oriented or may include any combination thereof depending on the particular embodiment. This facility may be paired with a single concentrator or may be paired with a plurality of concentrators in various embodiments. The containment facility may be of the same or different material with respect to the concentrating waveguide facility. As in the case of the concentrator facility the containment facility may be cylindrical, linearly polygonal, spherical, three dimensionally polygonal, and the like in its geometry and may be paired according to the geometry of the concentrator facility or be independent of the concentrator facility geometry. This facility may be filled with any class of materials gaseous, solid, liquid, and the like or a combination thereof wherein the material enhances the containment (internal reflection) or energy production of heat dissipation or use of a combination thereof properties of the containment element. The containment facility may entrain its input either vertically, horizontally, and the like depending on the embodiment and orientation of the concentrating element/s. The containment facility may entrain its input either exteriorly annularly, interior annularly, and the like or some combination thereof, output may be uniformly or non-uniformly distributed over the inner surface, and the like. The proportion of the containment unit to the aggregate area of power producing element may be determined by an optimal photoelectric material to photoelectric “interception” ratio wherein the cost of the energy converter may be substantially less if only a portion of the light may be intercepted over a period n time vs. the cost of energy converter element intercepting all or a higher proportion of the contained light. An additional parameter determining the optimal relationship and the effective “concentration” ratio achieved by the container may be the cost to efficiency proportion of the energy converter itself.

Any concentrator and containment system described herein may be combined either singularly or compoundly wherein the concentrator element requires only that it output the concentrated light into any of the types of containment facilities described herein and the containment element requires only a parameter of an input of light from any of the types of concentration facilities that are described herein or are generally known and understood by those of reasonable knowledge in the art. In a preferred embodiment the containment facility may be comprised of a contained gas, fluid, solid and the like that accepts a singular or plurality of annular inputs wherein the containment element may be paired with singular concentrators wherein the power producing element may be suspended in the medium. In a preferred embodiment the containment facility may be comprised of a gas, fluid, solid, and the like that accepts uniformly or non-uniformly distributed inputs wherein the containment element may be paired with multiple concentrators and the upper and lower surfaces may be of variable or grating geometry or the like and the power producing may be placed at an optimal central location.

With regard to the power production and transfer and/or storage facility, the power production facility and associated transfer and storage facilities may be centralized or networked. Power production and transfer facilities may be suspend in a medium within a containment element or may be exterior to the containment element. Said facility may be comprised of a networked array of energy converters, conditioners, and cables wherein the array may be formed as a integrated net or may formed with a combination of said elements and a support structure such a molded polymer sheet wherein active surfaces may be interior or exterior to said sheet. Said facility may be designed as a modular component and integrated with other modular components such as concentrator and containment components. The means of power transfer between the power producing components and the system output facility may be uniform or non-uniform in nature such as a web, node, tree and branch network structure, and the like or some combination thereof. Conditioning and storage may be collocated with the power producing elements, may be located at some optimized location within the transfer network, and the like. Power production may include singular or multiple types of power production methods including but not limited to PV, thermal differential, thermal flow, thermal combustion, thermal excitation systems, and the like.

As described light from a plurality of concentrator and containment facilities may be guided to a central facility or multi-feed facilities wherein the system power output would transferred out the system directly from said facilities or stored for leveling or future use purposes. As described a distributed facility may be embedded within a concentrator containment pair wherein the power produced may be transferred through a power collection network to a system output facility.

In a preferred embodiment modular concentrator and containment sheets may be sandwiched around a sheet of distributed PV crystalline, film elements, and the like singular to each concentrator-container pair suspended within a optically transparent polymer medium wherein the PV components may be arranged in an n×m matrix and connected by cables in a tree and branch or web configuration in series or in parallel or a combination thereof and thereby to a central transfer facility at the horizontal boundary of the sheet and a storage medium or the grid and wherein the PV components surfaces may be exterior or interior to the polymer and the cables may be interior and the sheet may include an attachment mechanism by which the sandwiching sheets may be held in place and the container elements thereby enclose the PV elements.

In a preferred embodiment a matrix of n×m PV crystalline or film elements of a module as described above singular to each concentrator-container pair may be suspended within a gaseous, fluid, solid, and the like or a combination thereof refractive medium encapsulated by a containment element wherein the containment element may be bisected around a central or non-central axis allowing the PV elements to be connected between encapsulated refractive containers and allowing ease of assembly. The PV element may be connected by a tree and branch, web structure, and the like and thereby to a positive and negative terminal at the horizontal boundary of the module. The concentrator element may attach to the upper surface of this structure by means and for purposes previously described. Said terminals may lock into terminals on other modules in such a way as to create an expanded power transfer network of a plurality of modules and in a manner previously described and thereby transfer the aggregate power of the modular array to a central storage facility or the grid.

In a preferred embodiment a waveguide module comprised of a refractive medium and exterior variable grating reflectors, with the lower surface containing the medium being reflective as previously described and the angle of the grating mechanism being determined by the angle of incidence to the module, may transfer light to a containment facility on the boundary of the module and a PV element may be suspended within the length of the containment element and connected at the orthogonal axis of the container boundary to positive and negative terminals that in turn connect to the adjoining module by means previously described. Thermal power may additional be gathered from fluid movement within the module by means known in the art and also connected to said terminals and thereby may form a network of modules wherein the aggregate solar and thermal power of the system may then be output to a storage facility or a grid.

Global optimization of the facilities described herein may include parameters for: cost of materials, effective lifecycle of materials, effective lifecycle of components, levelized replacement cost of components, legal and permitting costs, effective concentration ratio (inclusive of concentration and containment), ancillary system costs, efficiency of power conversion means, cost of power conversion means, complexity and cost of manufacture, complexity and cost of assembly, complexity and cost of installation, complexity and cost of deinstallation, complexity and cost of refurbishing, recycling, reconditioning and the like, complexity and cost of operation, complexity and cost of maintenance, cost of service, financing or purchase agreement type, historical and predicted market cost of electricity, cost of storage, cost and benefit of government regulations, systems efficiency, weather conditions, material environmental properties, historical and predicted irradiance, cost of insurance, quantified market acceptance boundaries, quantified market value proposition boundaries, scale cost mitigation, and the like.

While the invention has been described in connection with certain preferred embodiments, other embodiments would be understood by one of ordinary skill in the art and are encompassed herein.

All documents referenced herein are hereby incorporated by reference.

What is claimed is:

1. A system, comprising:
a multi-element photo power producing facility comprising:
i a waveguide element with a first side and a second side, wherein the geometry of the waveguide element is optimized to maximize both acceptance angle with respect to incident light entering the first side and concentration rate with respect to the incident light entering the first side and exiting the second side; and
ii a containment chamber element, wherein light exiting the second side of the waveguide element enters the containment chamber element, the containment chamber element comprising a suspended power producing element that is a fraction of the input area of the waveguide concentrator second side, and the geometry and of the containment chamber is adapted to minimize light escaping from the containment chamber to achieve a maximum concentration of light impinging upon the power producing element.

2. The system of claim 1, wherein the photo-power producing facility is a photoelectric power producing facility.

3. The system of claim 1, wherein the photo-power producing facility is a photo-thermal power producing facility.

4. The system of claim 1, wherein the compound waveguide element is a singular waveguide element.

5. The system of claim 1, wherein the compound waveguide element is a compound waveguide element.

6. The system of claim 1, wherein the containment chamber element acts as a lazing chamber.

7. The system of claim 1, wherein the compound waveguide element is comprised of at least one of a refractive and reflective optical element.

8. The system of claim 1, wherein the containment chamber element is comprised of at least one of a refractive and reflective optical element.

9. The system of claim 1, wherein a power producing element is a photovoltaic device.

10. The system of claim 1, wherein the power producing element is a thermal converter device.

11. The system of claim 1, wherein the multi-element photo power producing facility is disposed to maximize the ratio of incident to power producing mechanism area.
